(19) United States
(12) Patent Application Publication
(10) Pub. No.: US 2026/0328075 A1
(43) Pub. Date: Oct. 22, 2026

(54) SYSTEMS AND METHODS FOR OPTIMIZATION OF WELL OPERATIONS

(71) Applicant: ConocoPhillips Company, Houston, TX (US)

(72) Inventors: Dylan VENNES, Houston, TX (US); Syed SHIBLI, Houston, TX (US); Martin MLACNIK, Houston, TX (US); Kelly UMLAUF, Houston, TX (US); Mazaruny RINCONES, Houston, TX (US); Yong ZHAO, Houston, TX (US); Pallav SARMA, Houston, TX (US)

(21) Appl. No.: 19/555,091

(22) Filed: Mar. 3, 2026

Related U.S. Application Data
(60) Provisional application No. 63/766,277, filed on Mar. 3, 2025.

(51) Int. Cl. E21B 43/12; E21B 43/20

(52) U.S. Cl. CPC E21B 43/12; E21B 43/20; E21B 2200/20; E21B 2200/22

(57) ABSTRACT

Implementations described and claimed herein provide systems and methods for optimizing natural resource reservoirs and may include a processing system in communication with a computing device, one or more sensors and one or more databases over a network, the processing system retrieving reservoir simulation data, one or more well parameters, and one or more control inputs from at least one of the computing device, the one or more sensors, or the one or more databases. Systems and methods may include a forecast system generating forecast data by inputting the reservoir simulation data into one or more machine learning models, the one or more machine learning models trained using historical well data and reservoir physics. Systems and methods may include an injection well control system generating injection data for one or more injection wells using the forecast data, the one or more well parameters, and the one or more control inputs.

### CROSS-REFERENCE TO RELATED APPLICATIONS

The present application is related to U.S. Provisional Application No. 63/766,277, entitled “Water-Alternating Gas (WAG) Methodology” filed on Mar. 3, 2025, which is specifically incorporated by reference herein in its entirety.

### TECHNICAL FIELD

Aspects of the present disclosure relate generally to systems and methods for the optimization of well operations in natural resource reservoirs, and more particularly, to optimization of injection wells in natural resource reservoirs.

### BACKGROUND

Traditionally, production from natural resource reservoirs has relied on various enhanced recovery techniques, including water flooding and gas injection. However, these methods often face challenges in maintaining reservoir pressure and optimizing the balance between water and gas injection. Current solutions lack the ability to accurately describe well and reservoir properties, which results in inefficient enhanced recovery during natural resource production.

### SUMMARY

Implementations described and claimed herein address the foregoing problems by providing systems and methods for optimizing well operations in natural resource reservoirs and, more particularly, for optimizing injection wells in natural resource reservoirs using accurate forecasting.

In some implementations, the techniques described herein relate to a system for optimizing well operations in natural resource reservoirs, the system including: a processing system in communication with a computing device, one or more sensors and one or more databases over a network, the processing system retrieving reservoir simulation data, one or more well parameters, and one or more control inputs from at least one of the computing device, the one or more sensors, or the one or more databases; a forecast system generating forecast data by inputting the reservoir simulation data into one or more machine learning models, the one or more machine learning models trained using historical well data and reservoir physics; and an injection well control system generating injection data for one or more injection wells using the forecast data, the one or more well parameters, and the one or more control inputs.

In some implementations, the techniques described herein relate to a method for optimization of a natural resource reservoir, the method including: retrieving reservoir simulation data for the natural resource reservoir; generating forecast data by inputting the reservoir simulation data into one or more machine learning models, the one or more machine learning models trained using historical well data and reservoir physics; retrieving one or more well parameters and one or more control inputs; and generating injection data for one or more injection wells using the forecast data, the one or more well parameters, and the one or more control inputs.

In some implementations, the techniques described herein relate to one or more tangible non-transitory computer-readable storage media storing computer-executable instructions for performing a computer process on a computing system, the computer process including: retrieving reservoir simulation data for a natural resource reservoir; generating forecast data by inputting the reservoir simulation data into one or more machine learning models, the one or more machine learning models trained using historical well data and reservoir physics; retrieving one or more well parameters and one or more control inputs; and generating injection data for one or more injection wells using the forecast data, the one or more well parameters, and the one or more control inputs.

In some implementations, the disclosed systems and methods provide efficient scheduling, evaluation, and forecasting of injection scenarios, thereby significantly reducing setup time, to prioritize optimizing results. In some implementations, the systems and methods described herein provide accurate forecast and injection data that is used to schedule injections. In some implementations, the systems and methods provide automated scheduling which streamlines operations and maximizes economic oil production by optimizing injection scenarios.

In some implementations, systems and methods disclosed herein provide physics-based approaches to generate and quantitatively optimize different scenarios to predict a maximum, quantified, predictable, and risk-adjusted return with regards to natural resource production. In some implementations, injection and resource production activities may be generated and efficiently analyzed (e.g., increased injection, resource production, etc.) in order to provide optimal forecast information for scheduling injections based on one or more scenarios.

In some implementations, the techniques described herein generate easy-to-use visual output, such as interfaces and/or dashboards that facilitate understanding of parameters and/or control inputs that affect production and/or injection activities, making evaluation of injection activities and resource production more transparent and accessible. In some implementations, the techniques described herein consider real-world constraints and optimal injection patterns, thereby ensuring that injection activities are balanced and optimized according to user specifications and/or overall development goals.

Other implementations are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modifications in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

FIG. 1 illustrates an example system for optimizing development plans for injection wells.

FIG. 2 illustrates an example processing system for optimizing development plans for injection wells.

FIG. 3 illustrates an example computing system that may implement various aspects of the systems discussed herein.

FIG. 4A illustrates an example graphical illustration for two different gas injection scenarios.

FIG. 4B illustrates an example graphical illustration for two different water injection scenarios.

FIG. 5A illustrates an example gas injection and example forecast gas injection data.

FIG. 5B illustrates an example gas injection from historical MCFD injection and example forecast gas injection data.

FIG. 6A illustrates example available injectors or producers for forecasting and scheduling.

FIG. 6B illustrates example variable or last month voidage and an example visualization for a selected well.

FIG. 7 illustrates example operations for optimization of well operations in a natural resource reservoir using the various systems described herein.

### DETAILED DESCRIPTION

Implementations of the present disclosure involve systems and methods for optimizing natural resource reservoirs, and specifically for the optimization of injection wells. Disclosed systems and methods more particularly include forecasting injection data and optimizing injector and producer wells in a natural resource reservoir. In some implementations, historical data for injector and producer wells is input into a data physics framework, which combines machine learning and reservoir physics into a unified model where the model uses the historical data and production forecast data to generate injection data and schedule injections, thereby improving production of the natural resource reservoir.

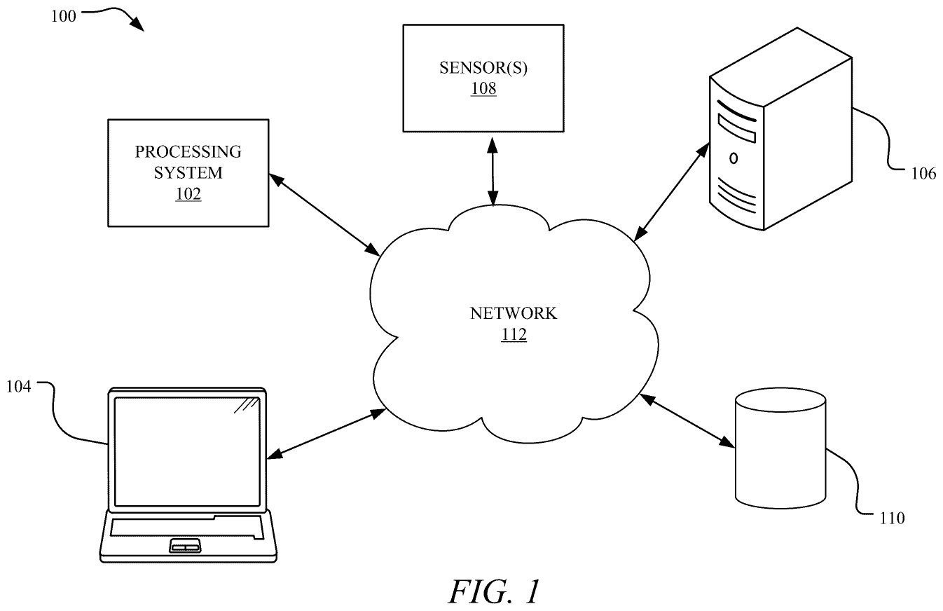

FIG. 1 illustrates an example system 100 that may implement various systems and methods discussed herein. The system 100 may include a processing system 102 configured to communicate with one or more user devices 104, one or more servers 106, one or more sensors 108, and/or one or more databases 110 via a network 112.

As depicted in FIG. 1, a network 112 may be used by one or more computing devices or data storage devices for implementing the systems and methods for optimization of injection well(s). In one implementation, various components of the system 100, one or more user devices 104, one or more servers 106, one or more sensors 108, one or more databases 110, and/or other network components or computing devices described herein are communicatively connected to the network 112.

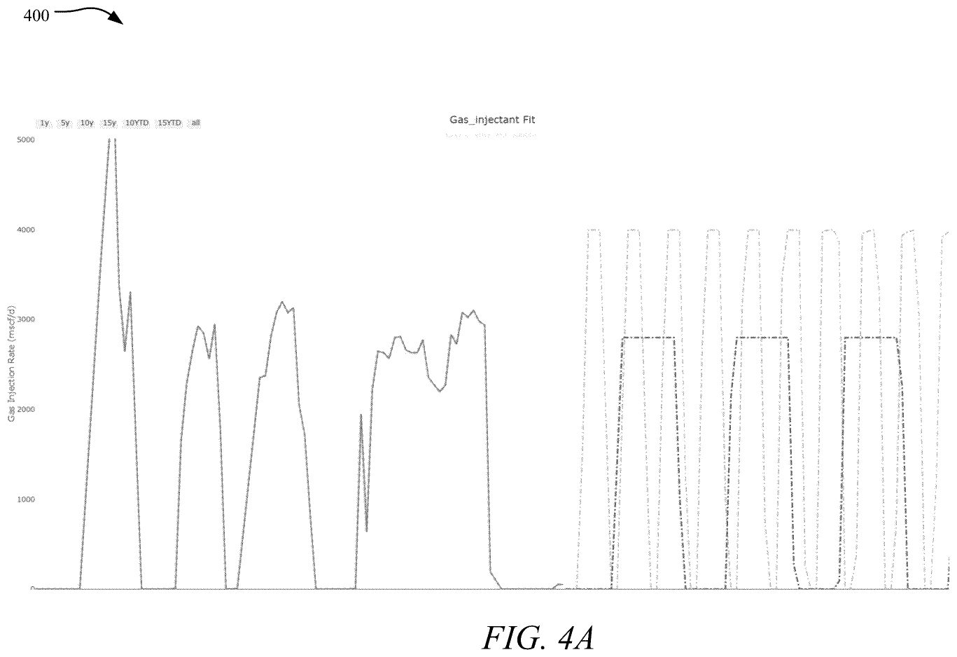

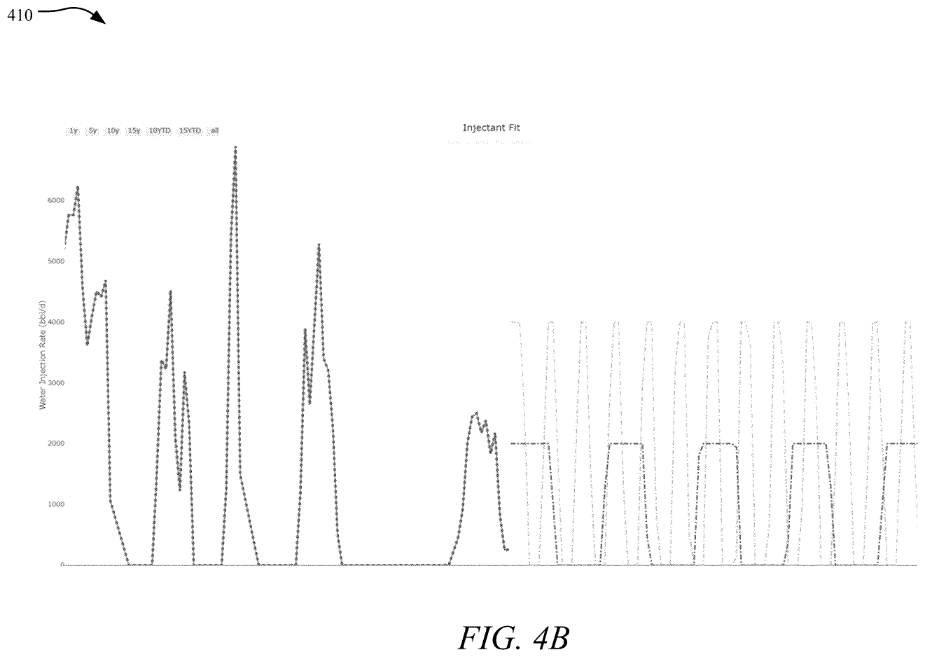

The system 100 is configured to receive user input via one or more input systems using, for example, the user device 104 to input text, audio, and/or interact with an interactive user interface displayed on one or more output systems of, for example, the user device 104. The user device 104 can be a terminal, personal computer, smartphone, tablet, laptop, workstation, or other personal computing device used by an individual (e.g., the operator) to receive notifications and enter data via one or more input and/or output systems. These systems may be part of or separate from the user device 104. For instance, the operator can input data related to one or more wells into the processing system 102 through interactive user interfaces on the user device 104. In some cases, the user device 104 may output data such as display plots, analytical information, forecast data, optimized development plans, injection scenarios, notifications, and alerts using graphical user interfaces, like those illustrated in FIGS. 4A-6B. The user interface may also be used to interact with data, including graphical representations from FIGS. 4A-6B, training data, forecasts, development plans, production maps, injection scenarios, and variances between different data sets, as non-limiting examples.

In some examples, the server 106 may host the system. Additionally or alternatively, the server 106 may host a website or an application that users may visit to access the system 100. The server 106 may be a single server, a plurality of servers with each server being a physical server or a virtual machine, or a collection of physical servers and virtual machines. In another implementation, a cloud hosts one or more components of the system. The system 100, the user devices 104, the server 106, and other resources connected to the network 112 may access one or more additional servers for access to one or more websites, applications, web services, interfaces, etc. that are used for resource development and/or injection activities. In one implementation, the server 106 may also host a search engine that the system uses for accessing and modifying information, including without limitation, reservoir data, parameters, user interfaces, etc.

In some examples, at least a portion of the data is obtained by one or more sensors 108 disposed in a well or at a surface during well tests, reservoir tests, and/or well operations (e.g., oil production, gas production, water production, gas injection, water injection, performance of a water-alternating-gas (WAG) technique, etc.). For instance, pressure, temperature, and/or flow rates may be continuously monitored throughout operation of a well using one or more pressure sensors, one or more temperature sensors, and/or one or more flow rate sensors. In an implementation, the reservoir data is received directly from the one or more sensors 108 via a wired or wireless connection. As illustrated in greater detail below, any and/or all of the processing system 102, the user device(s) 104, and the one or more databases 110 may, in some instances, be special-purpose computing devices configured to perform specific functions.

In one implementation, the one or more databases 110 may be used to store reservoir data, such as structured and unstructured data captured from disparate sources associated with wells, reservoir(s), etc. Some of the data may be captured directly, for example using one or more sensors 108 deployed at wells, reservoir(s), etc. Such data may include historical information obtained via the one or more sensors 108 and/or other sources. Such data may include core, well log, fluid sampling, production rates (e.g., resource produced per unit time), injection rates (e.g., tracking the volumes of water and gas injected), pressure data, location data, top hole pressure, bottom hole pressure, reservoir pressure, temperature, fluid flow rates, etc. Additionally or alternatively, some of the data may be obtained from public sources in accordance with regulatory requirements. In some examples, the reservoir data may include data input or otherwise obtained via an interface, at the direction of one or more computing units, and/or the like. In some examples, the one or more databases 110 may be used to store training data, forecast data, production plans, injection plans, development plans, optimization, input data, and/or output data.

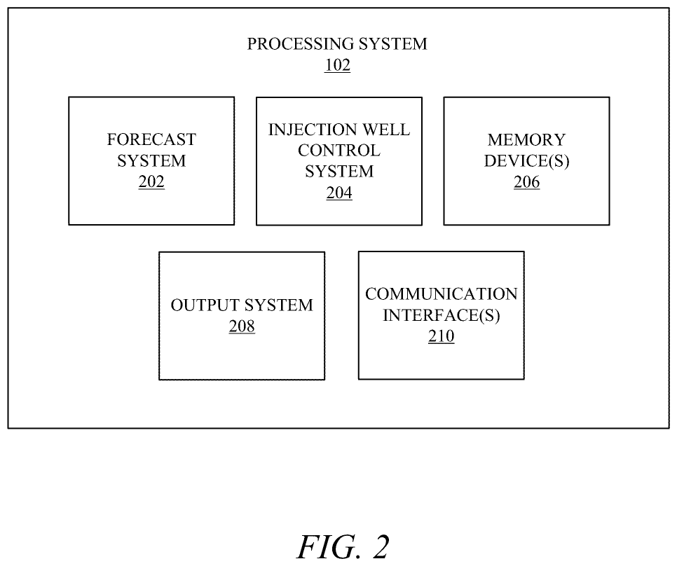

FIG. 2 illustrates the processing system 102 which can include one or more computing devices (e.g., servers, routers, user interface devices, internet telephony computing device, and the like) that store and/or retrieve data in the one or more databases 110, generate user interfaces, etc. The processing system 102 includes a forecast system 202, an injection well control system 204, one or more memory device(s) 206, an output system 208, and/or communication interface(s) 210. The communication interface(s) 210 can communicate with the one or more input systems and one or more output systems of one or more computing devices via the network(s) 112. For instance, the communication interface(s) 210 may be a network interface configured to support communication between the processing system 102 and the network(s) 112.

The processing system 102 can be configured to execute one or more algorithms to perform the techniques, as discussed in greater detail below. For instance, the one or more algorithms can include one or more machine learning algorithms. The one or more machine learning algorithms can be one or more models, such as, for example, a linear regression model, an unsupervised neural network model, gradient boosted trees, random decision forest, etc. The one or more machine learning models may be built from historical data associated with natural resource reservoirs and/or events for an area, such as a production field that includes natural resource reservoirs, and may be stored, for example, at one or more databases. Thus, the one or more machine learning models leverage historical data to generate optimized development plans. The processing system 102 can be configured to monitor and store (e.g., with appropriate permissions) data for further analysis and/or training of the machine learning model(s). In an implementation, the processing system 102 is configured to transmit data related to the machine learning model(s) to another computing device or database, such as the one or more databases 110. In an implementation, the processing system 102 is associated with an organization or entity.

In an implementation, the processing system 102 includes instructions that direct and/or cause the forecast system 202 to execute processing techniques on reservoir data to generate one or more reservoir simulations using the reservoir data. The forecast system 202 may use a small amount of reservoir data available to generate one or more reservoir models. The one or more reservoir models may be a Low order continuous scale simulation (LOCSIM) model, which is a mixed domain decomposition method for comprehensive modeling of connected fault vectors. The LOCSIM model allows modeling flows with open, partially open and closed faults, and/or a dual point scheme-based no-flow boundaries. The one or more models may utilize a radial basis function (RBF), which is a real-valued function φ whose value depends only on the distance between the input and some fixed point, either the origin, so that φ(x)=φ\hat{ }(∥x∥), or some other fixed point c, called a center, so that φ(x)=φ\hat{ }(∥x−c∥). Any function φ that satisfies the property φ(x)=φ\hat{ }(∥x∥) is a radial function. The RBFs can be used to approximate solutions for areas where data is not available (e.g., at some well locations, production sites, and/or injection sites). The reservoir simulation data may be one or more models of a reservoir and/or reservoir properties (e.g., reservoir simulation data). In some examples, the reservoir simulation data may include simulation data for more than one reservoir and/or reservoir field.

The reservoir simulation data may be used by the forecast system 202 to create a forecast and/or optimized development plan for one or more wells, reservoirs, etc. For example, the forecast system 202 may apply one or more machine learning models to the reservoir simulation data. The forecast system 202 utilizes the reservoir simulation data, a data physics engine, and an ensemble-based approach with multiple realizations (MR) to produce forecast data.

The data physics engine combines machine learning and physics models to simulate reservoir properties while maintaining realistic physics constraints. Reservoir properties are input into the engine to generate predicted properties. Discrepancies are quantitatively captured using methods like Ensemble Smoothing with Multiple Data Assimilation (ESMDA) and an Ensemble Kalman filter (EnKF) to update uncertainty based on variances between forecast and actual data. The system ensures efficient data smoothing by executing smoothing functions multiple times using ESMD and/or EnKF. The data physics engine, updated with a minimized vector RBF representation, refines uncertainty through an ensemble-based MR process. Flow equations are solved in each realization with minimal solution points and approximated using continuous functions for a high-resolution model with reduced uncertainty.

The forecast system 202 generates solutions approximated with continuous functions for high-resolution production forecasts. The executed processes are automated with minimal or no user input and integrated for rapid model calibration and forecasting, allowing recalibration with new data inputs. Embedding the ESMDA/EnKF process accounts for multiple uncertainties in the data. This structured approach ensures that the forecast system 202 effectively manages uncertainty and enhances model accuracy through integrated processes and advanced algorithms.

Training involves inputting parameters like resource production or injection rates. For example, oil, water, and gas production and injection rates during WAG cycles may be input. The training may begin with a larger dataset followed by a limited dataset for back-testing, using ESMDA iterations for preconditioning and EnKF. The number of training iterations can be customized, ranging from 1-10, 1-50, 1-100, as non-limiting examples. The forecast system 202 may provide the forecast data to the injection well control system 204 and/or to an output system 208 for generating one or more optimized development plans, injection scenarios, visual dashboards, graphical representations, etc.

The injection well control system 204 may execute processing techniques to generate injection data, commands for performing injections, and/or schedule injections using the forecast data received from the forecast system 202. The injection well control system 204 may schedule, control, and/or execute injections of injection well(s). The injection well control system 204 may incorporate real-life constraints and optimal patterns for injection to maximize economic oil production by using received forecast data, one or more well parameters, and/or one or more control inputs and perform an analysis to determine one or more optimum injection scenarios for one or more wells. In some implementations, the injection scenarios can be generated to automatically consider cumulative water and gas injected, along with well parameters and/or control inputs to produce injection data. In some implementations, the injection well control system transmits executable control commands to surface or downhole injection equipment, including pump controllers, valve actuators, and/or pressure regulators, thereby physically altering injection rates and bottom-hole pressure in real time.

The one or more well parameters and one or more control inputs may be received from one or more databases 110, may be input by a user, etc. The well parameters may be hydrocarbon pore volume (HCPV), slug size, WAG ratio, water and gas slug target volume, default injection BHP for gas, default injection BHP for water, target gas injection rates, cumulative gas injection volume, cumulative water injection volume, gas cycle length, water cycle length, cumulative gas injection limit, gas injection rate, or water injection rate. The control inputs may be gas bottom hole pressure (BHP), maximum water BHP, or priority information. In some implementations, priority information may include gas and water cycle lengths, equipment location, reservoir pressure, or historical production rates. In some implementations, the well parameters may be user-defined.

The injection well control system 204 may provide injection scenarios, schedule injections, and/or execute injection activities based on the one or more control inputs. In some implementations, the injection well control system 204 can limit injections based on one or more control inputs or priority information provided. For example, the injection well control system 204 can limit maximum bottom-hole pressure (BHP) based on maximum BHP values input. In some implementations, the injection well control system 204 evaluates voidage to produce injection data that ensures a balanced approach to injection activities. In some implementations, the injection well control system 204 may perform a pattern-centered analysis on one or more wells and use the analysis in optimizing injection data. In some implementations, the injection well control system considers both short-term production goals and long-term production goals, as well as short-term and long-term injection activities, thereby ensuring that producer controls align with injection activities. In some implementations, the injection well control system 204 automates scheduling.

The injection well control system 204 may provide injection data as an output. The injection data may encompass maximum gas and water BHP, maximum gas and water rates, and/or cycle information. The injection well control system 204 may provide injection data, such as scenarios, schedules, etc. to the output system 208. For example, the injection well control system 204 can provide information on gas or water cycles completed or remaining, or if wells are in a permanent water injection state.

The output system 208 may execute processing techniques to output one or more injection scenarios or development plans generated by the injection well control system 204 based on the forecast data received from the forecast system 202. In some implementations, the output of the development plan may include visual representations, such as plots, maps, pressure maps, bar graphs, or other graphical illustrations that may be provided via user interface on for example, a computing device, such as user device 104. For example, the output system 208 may present one or more dashboards for visualizing results, enhancing prediction accuracy for better reservoir management. A user may modify the output of the development plan to input new data and/or update the output. For example, the output system 208 may present injection data or injection scenarios for one or more wells, and a user may select injection data or an injection scenario, which causes the injection well control system 204 to modify an injection schedule, control an injection based on the scenario selected, execute injection activities, and/or update the ouput injection data. In some implementations, the injection well control system 204 may automatically control one or more injection wells.

Data may be exchanged sequentially and/or simultaneously among the forecast system 202, the injection well control system 204, and/or the output system 208 so that the systems may coordinate while executing processing techniques. The forecast system 202 and/or the injection well control system 204 can be configured to execute one or more algorithms to perform the techniques. For instance, the one or more algorithms can include one or more machine learning algorithms. The one or more machine learning algorithms can be one or more models, such as, for example, a linear regression model, an unsupervised neural network model, gradient boosted trees, random decision forest, etc. The one or more machine learning models may be built from well data, which can be historical data associated with oil, water, and gas production systems or water and gas injection systems that is stored, for example, at one or more databases 110. In some implementations, the well data includes water-cut (water content in produced fluid), gas-oil ratio (GOR) (ratio of gas produced to oil produced), temperature of the produced fluids (e.g., to identify potential thermal effects or changes in reservoir conditions), fluid responsivity, saturation levels, cumulative production, oil viscosity (resistance of oil to flow), etc. In an implementation, resource production (e.g., gas, oil, water, etc.) and/or injection data is generated by processing large amounts of data associated with a large number of oil, gas, and water production and injection systems. In some implementations, the processing is performed in real-time or near real-time, to allow for analysis of resource production systems to assist in optimization decisions, such as, for example, development plans involving injection cycles, resource production, well spacing, well completions, well designs, lateral information, conduit placement, protests of well permits, well operations (e.g., drilling schedules), and/or legal agreements, as non-limiting examples.

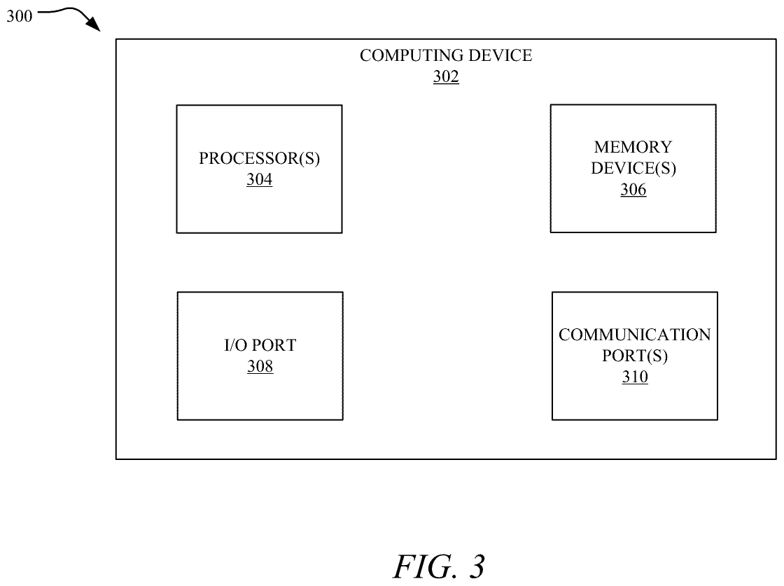

Referring to FIG. 3, a detailed description of an example computing system 300 having at least one computing device 302 that may implement various systems and methods discussed herein is provided. The computing device 302 may be applicable to the system 100, the server 106, the user devices 104, the processing system 102, and other computing or network devices. It will be appreciated that specific implementations of these devices may be of differing possible specific computing architectures not all of which are specifically discussed herein but will be understood by those of ordinary skill in the art.

In some instances, the computing device 302 can include a computer, a personal computer, a desktop computer, a laptop computer, a terminal, a workstation, a server device, a cellular or mobile phone, a mobile device, a smart mobile device, a tablet, a wearable device (e.g., a smart watch, smart glasses, a smart epidermal device, etc.) a multimedia console, a television, an Internet-of-Things (IoT) device, a smart home device, a medical device, a virtual reality (VR) or augmented reality (AR) device, a vehicle (e.g., a smart bicycle, an automobile computer, etc.), and/or the like. The computing device 302 may be integrated with, form a part of, or otherwise be associated with the systems described herein. It will be appreciated that specific implementations of these devices may be of differing possible specific computing architectures not all of which are specifically discussed herein but will be understood by those of ordinary skill in the art.

The computing device 302 may be a computing system capable of executing a computer program product to execute a computer process. Data and program files may be input to the computing device 302, which reads the files and executes the programs therein. Some of the elements of the computing device 302 include one or more processors 304, one or more memory devices 306, and/or one or more ports, such as input/output (IO) port(s) 308 and communication port(s) 310. Additionally, other elements that will be recognized by those skilled in the art may be included in the computing device 302 but are not explicitly depicted in FIG. 3 or discussed further herein. Various elements of the computing device 302 may communicate with one another by way of the communication port(s) 310 and/or one or more communication buses, point-to-point communication paths, or other communication means.

The processor 304 may include, for example, a central processing unit (CPU), a microprocessor, a microcontroller, a digital signal processor (DSP), and/or one or more internal levels of cache. There may be one or more processors 304, such that the processor 304 comprises a single central-processing unit, or a plurality of processing units capable of executing instructions and performing operations in parallel with each other, commonly referred to as a parallel processing environment.

The computing device 302 may be a conventional computer, a distributed computer, or any other type of computer, such as one or more external computers made available via a cloud computing architecture. The presently described technology is optionally implemented in software stored on the data storage device(s) such as the memory device(s) 306, and/or communicated via one or more of the I/O port(s) 308 and the communication port(s) 310, thereby transforming the computing device 302 in FIG. 3 to a special purpose machine for implementing the operations described herein. Moreover, the computing device 302, as implemented in the systems in FIGS. 1-3, receives various types of input data (e.g., the sensor data, reservoir data, well data, etc.) and transforms the input data through various stages of the data flow into new types of data files (e.g., well development plans, optimization data, etc.). Moreover, these new data files are transformed further into output data and sent to the computing device 302 to provide information regarding the data, which enables the computing device 302 to do something it could not do before—using injection data based on accurate and reliable forecast data to optimize well operations, including injection activities.

The one or more memory device(s) 306 may include any non-volatile data storage device capable of storing data generated or employed within the computing device 302, such as computer executable instructions for performing a computer process, which may include instructions of both application programs and an operating system (OS) that manages the various components of the computing device 302. The memory device(s) 306 may include, without limitation, magnetic disk drives, optical disk drives, solid state drives (SSDs), flash drives, and the like. The memory device(s) 306 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory device(s) 306 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the memory device(s) 306 which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computing device 302 includes one or more ports, such as the I/O port(s) 308 and the communication port(s) 310, for communicating with other computing, network, or vehicle computing devices. It will be appreciated that the I/O port 308 and the communication port 310 may be combined or separate and that more or fewer ports may be included in the computing device 302. The I/O port 308 may be connected to an I/O device, or other device, by which information is input to or output from the computing device 302. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing device 302 via the I/O port 308. Similarly, the output devices may convert electrical signals received from the computing device 302 via the I/O port 308 into signals that may be sensed as output by a human, such as sound, light, and/or touch. The input device may be an alphanumeric input device, including alphanumeric and other keys for communicating information and/or command selections to the processor 304 via the I/O port 308. The input device may be another type of user input device including, but not limited to direction and selection control devices, such as a mouse, a trackball, cursor direction keys, a joystick, and/or a wheel; one or more sensors, such as a camera, a microphone, a positional sensor, an orientation sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

In some implementations, environment transducer devices may convert one form of energy or signal into another for input into or output from the computing device 302 via the I/O port 308. For example, an electrical signal generated within the computing device 302 may be converted to another type of signal, and/or vice-versa. In one implementation, the environment transducer devices sense characteristics or aspects of an environment local to or remote from the computing device 302, such as, light, sound, temperature, pressure, magnetic field, electric field, chemical properties, physical movement, orientation, acceleration, gravity, and/or the like.

In one implementation, the communication port 310 is connected to the network(s) 112 so the computing device 302 can receive network data useful in executing the methods and systems set out herein as well as transmitting information and network configuration changes determined thereby. Stated differently, the communication port 310 connects the computing device 302 to one or more communication interface devices configured to transmit and/or receive information between the computing device 302 and other devices by way of one or more wired or wireless communication networks or connections. Examples of such networks or connections include, without limitation, Universal Serial Bus (USB), Ethernet, Wi-Fi, Bluetooth®, Near Field Communication (NFC), and so on. One or more such communication interface devices may be utilized via the communication port 310 to communicate with one or more other machines, either directly over a point-to-point communication path, over a wide area network (WAN) (e.g., the Internet), over a local area network (LAN), over a cellular network (e.g., third generation (3G), fourth generation (4G), Long-Term Evolution (LTE), fifth generation (5G), etc.) or over another communication means. Further, the communication port 310 may communicate with an antenna or other link for electromagnetic signal transmission and/or reception.

The computing device 302 set forth in FIG. 3 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Additionally, the systems and operations disclosed herein represent an improvement to the technical field of predictive modeling. For instance, the processing system 102 can generate an optimized development plan from available data related to a plurality of resource production and/or injection systems. Moreover, the optimized development plan can be leveraged to provide a highly efficient and effective analysis of resource production and injection systems. As described above, the forecasting may be performed in part, by using resource production training data and/or injection data, such as water production, oil production, gas production, gas injection, water injection, etc. In some examples, the disclosed system reduces computational load by utilizing a minimized vector RBF representation combined with ensemble-based uncertainty reduction, thereby enabling real-time physical injection control. The integration of ensemble smoothing and minimized vector RBF representations can reduce computational complexity and memory utilization compared to traditional reservoir simulation techniques.

FIG. 4A illustrates an example graphical illustration 400 for two different gas injection scenarios. FIG. 4B illustrates an example graphical illustration 410 for two different water injection scenarios. In some implementations, a user may select one of the two scenarios for scheduling and/or execution. In some implementations, one of the scenarios may automatically be executed by the injection well control system 204.

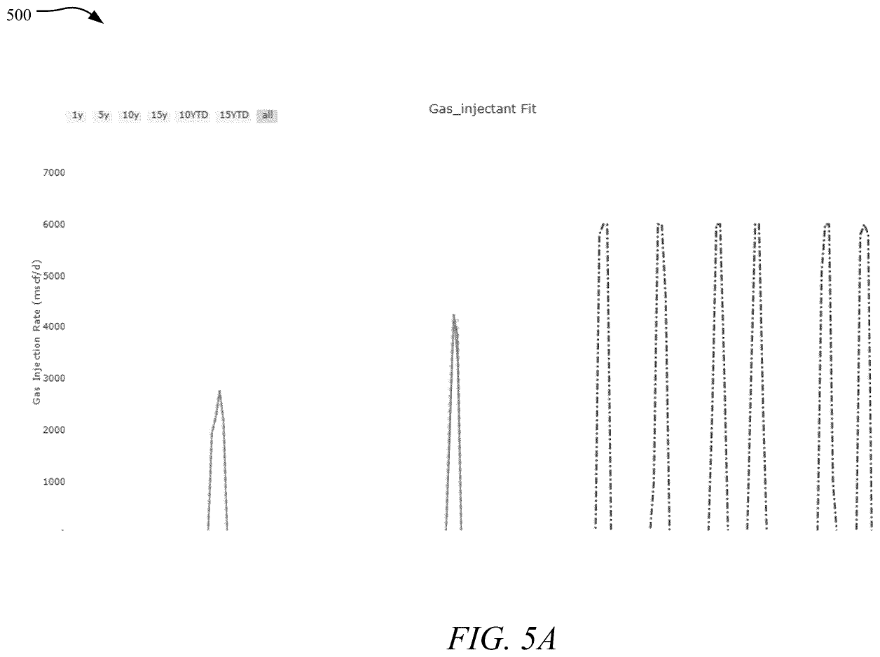

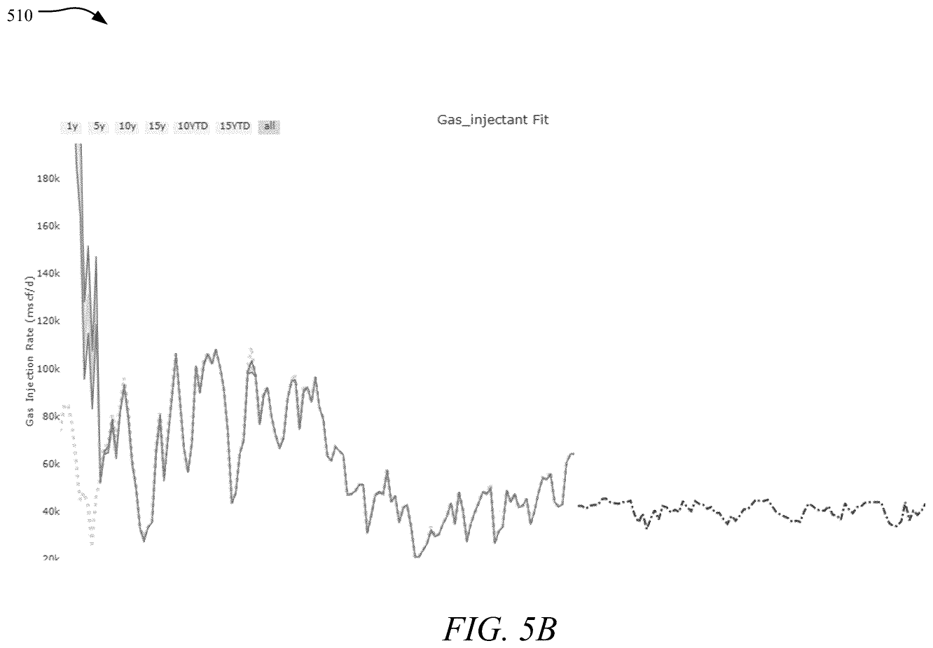

FIG. 5A illustrates an example gas injection 500 from historical thousand cubic feet per day (MCFD) injection and forecast gas injection data from left to right. FIG. 5B illustrates an example gas injection 510 from historical MCFD injection and forecast gas injection data from left to right. In some implementations, control inputs may be modified to provide updated forecast gas injection data and visualize the effects the modification. For example, FIG. 5B illustrates forecast gas injection data with a 40,000 MCFD constraint (+/−10%).

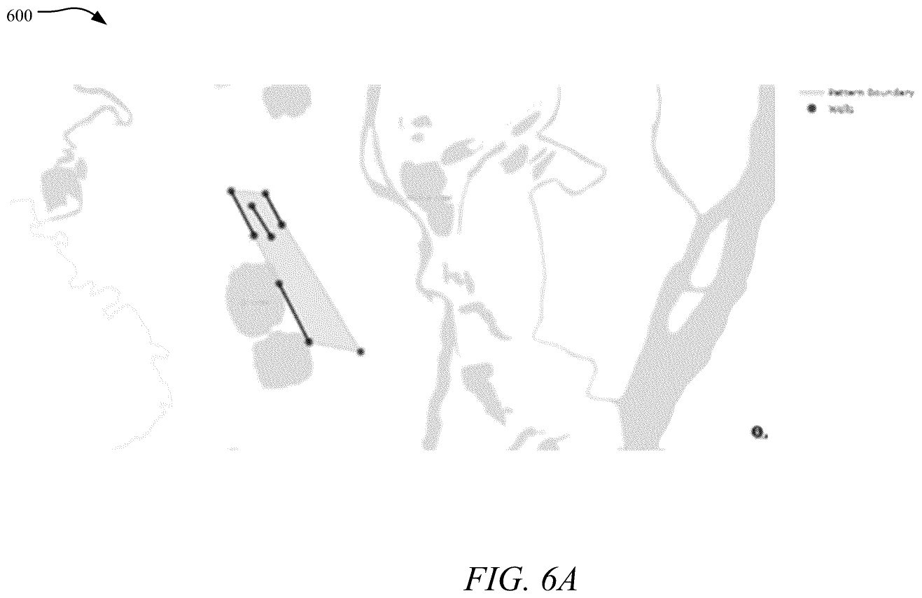

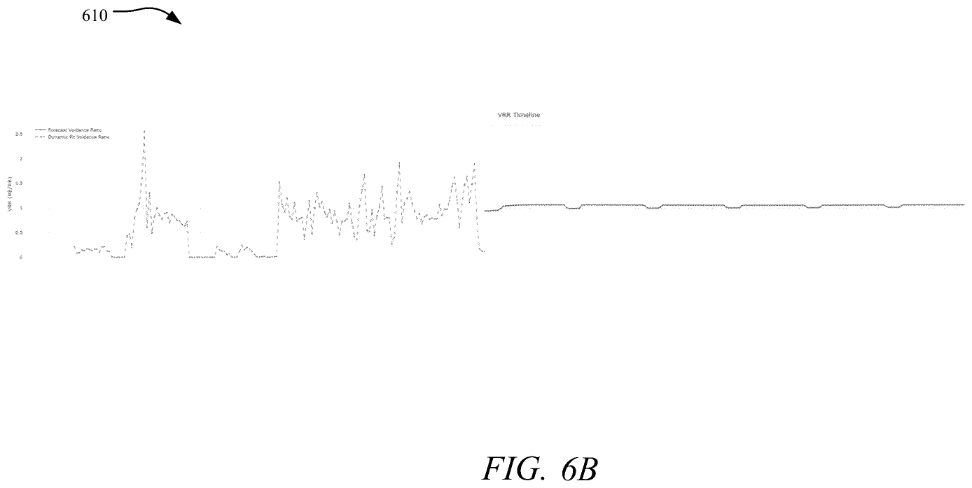

FIG. 6A illustrates example available injectors or producers 600 for forecasting and scheduling. In some implementations, different injectors or producers may be selected to view forecast and/or injection data for the selected injection and/or production wells.

FIG. 6B illustrates an example variable voidage and an example forecast, schedule, or pressure visualization 610 for a selected well, such as for example a well selected in FIG. 6A. The variable voidage data may be historical data for a period of time. The forecast, schedule, or pressure visualization may be presented based on a user selection and/or upon generation of injection data, as a non-limiting example.

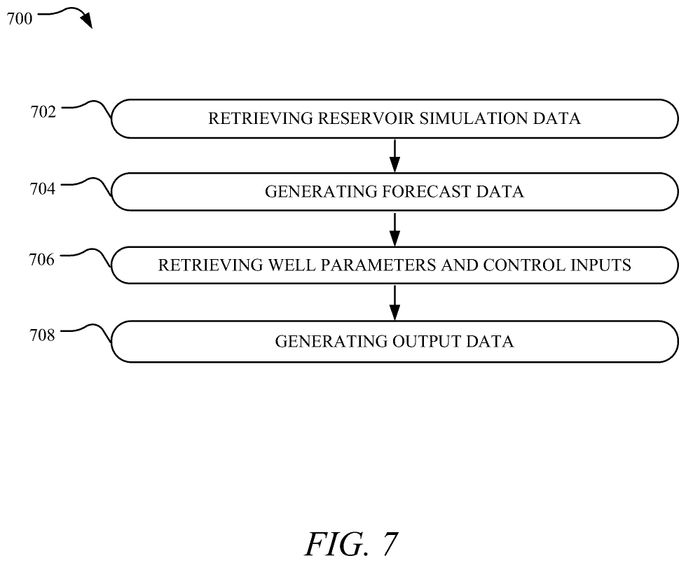

FIG. 7 illustrates example operations 700 for optimization of well operations in a natural resource reservoir using the various systems and methods described herein. In one implementation, an operation 702 retrieves reservoir simulation data from one or more databases 110, another computing system, etc.

An operation 704, forecast data is generated using the reservoir simulation data. For example, the forecast system 202 may use one or more models of a reservoir and/or reservoir properties, historical well data, and reservoir physics to generate the forecast data.

An operation 706 receives one or more well parameters and one or more control inputs. The well parameters may be hydrocarbon pore volume (HCPV), slug size, WAG ratio, water and gas slug target volume, default injection BHP for gas, default injection BHP for water, target gas injection rates, cumulative gas injection volume, cumulative water injection volume, gas cycle length, water cycle length, cumulative gas injection limit, gas injection rate, or water injection rate. The control inputs may be gas bottom hole pressure (BHP), maximum water BHP, or priority information. In some implementations, priority information may include gas and water cycle lengths, equipment location, reservoir pressure, or historical production rates. In some implementations, the well parameters and/or control inputs may be user-defined or input by a user or retrieved from one or more databases 110.

In an implementation, operation 708 may generate output data. For example, the output system 208 may output visual representations, such as plots, maps, pressure maps, bar graphs, or other graphical illustrations that may be provided via user interface on for example, a computing device, such as user device 104. In some implementations, the output system 208 may present one or more dashboards for visualizing results, which may be modified by a user to input new data and/or update the displayed output. For example, the output system 208 may present injection data or injection scenarios for one or more wells, and a user may select injection data or an injection scenario which causes the injection well control system 204 to modify an injection schedule, control an injection based on the scenario selected, executed injection activities, and/or update the output injection data.

In the present disclosure, the methods disclosed may be implemented as sets of instructions or software readable by a device. Further, it is understood that the specific order or hierarchy of steps in the methods disclosed are instances of example approaches. Based upon design preferences, it is understood that the specific order or hierarchy of steps in the method can be rearranged while remaining within the disclosed subject matter. The accompanying method claims present elements of the various steps in a sample order and are not necessarily meant to be limited to the specific order or hierarchy presented.

The described disclosure may be provided as a computer program product, or software, which may include a non-transitory machine-readable medium having stored thereon instructions, which may be used to program a computer system (or other electronic devices) to perform a process according to the present disclosure. A machine-readable medium includes any mechanism for storing information in a form (e.g., software, processing application) readable by a machine (e.g., a computer). The machine-readable medium may include, but is not limited to, magnetic storage medium, optical storage medium; magneto-optical storage medium, read only memory (ROM); random access memory (RAM); erasable programmable memory (e.g., EPROM and EEPROM); flash memory; or other types of medium suitable for storing electronic instructions.

While the present disclosure has been described with reference to various implementations, it will be understood that these implementations are illustrative and that the scope of the present disclosure is not limited to them. Many variations, modifications, additions, and improvements are possible. More generally, embodiments in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A system for optimizing well operations in natural resource reservoirs, the system comprising:
a processing system in communication with a computing device, one or more sensors and one or more databases over a network, the processing system retrieving reservoir simulation data, one or more well parameters, and one or more control inputs from at least one of the computing device, the one or more sensors, or the one or more databases;
a forecast system generating forecast data by inputting the reservoir simulation data into one or more machine learning models, the one or more machine learning models trained using historical well data and reservoir physics; and
an injection well control system generating injection data for one or more injection wells using the forecast data, the one or more well parameters, and the one or more control inputs.

2. The system of claim 1, further comprising:
an output system generating one or more outputs using the injection data.

3. The system of claim 1, wherein the one or more outputs include one or more user interfaces presenting the injection data, wherein the injection data is selectable and usable to control the one or more injection wells.

4. The system of claim 1, wherein the one or more control inputs include at least one of maximum gas bottom hole pressure (BHP), maximum water BHP, or priority information.

5. The system of claim 1, wherein the one or more well parameters includes hydrocarbon pore volume (HCPV), slug size, WAG ratio, water and gas slug target volume, default injection BHP for gas, default injection BHP for water, target gas injection rates, cumulative gas injection volume, cumulative water injection volume, gas cycle length, water cycle length, cumulative gas injection limit, gas injection rate, or water injection rate.

6. A method for optimization of well operations in a natural resource reservoir, the method comprising:
retrieving reservoir simulation data for the natural resource reservoir;
generating forecast data by inputting the reservoir simulation data into one or more machine learning models, the one or more machine learning models trained using historical well data and reservoir physics;
retrieving one or more well parameters and one or more control inputs; and
generating injection data for one or more injection wells using the forecast data, the one or more well parameters, and the one or more control inputs.

7. The method of claim 6, further comprising:
scheduling one or more injections for the one or more injection wells based on the injection data.

8. The method of claim 6, wherein the one or more well parameters includes at least one of hydrocarbon pore volume (HCPV), slug size, WAG ratio, water and gas slug target volume, default injection BHP for gas, default injection BHP for water, target gas injection rates, cumulative gas injection volume, cumulative water injection volume, gas cycle length, water cycle length, cumulative gas injection limit, gas injection rate, or water injection rate.

9. The method of claim 6, wherein the one or more control inputs includes at least one of maximum gas bottom hole pressure (BHP), maximum water BHP, or priority information.

10. The method of claim 6, wherein the priority information includes at least one of gas and water cycle lengths, equipment location, reservoir pressure, or historical production rates.

11. The method of claim 6, further comprising generating one or more user interfaces outputting the injection data.

12. The method of claim 6, further comprising receiving a selection of the injection data.

13. The method of claim 6, further comprising executing an injection process based on the injection data.

14. The method of claim 6, wherein the injection data provides at least one of a number of gas or water cycles completed, a number of remaining gas or water cycles, or whether the one or more injection wells are in a permanent water injection state.

15. One or more tangible non-transitory computer-readable storage media storing computer-executable instructions for performing a computer process on a computing system for optimization of well operations in natural resource reservoirs, the computer process comprising:
retrieving reservoir simulation data for a natural resource reservoir;
generating forecast data by inputting the reservoir simulation data into one or more machine learning models, the one or more machine learning models trained using historical well data and reservoir physics;
retrieving one or more well parameters and one or more control inputs; and
generating injection data for one or more injection wells using the forecast data, the one or more well parameters, and the one or more control inputs.

16. The one or more tangible non-transitory computer-readable storage media of claim 15, the computer process further comprising scheduling one or more injections for the one or more injection wells using the injection data.

17. The one or more tangible non-transitory computer-readable storage media of claim 15, wherein the injection data provides at least one of a number of gas or water cycles completed, a number of remaining gas or water cycles, or whether the one or more injection wells are in a permanent water injection state.

18. The one or more tangible non-transitory computer-readable storage media of claim 15, wherein the one or more well parameters include hydrocarbon pore volume (HCPV), slug size, WAG ratio, water and gas slug target volume, default injection BHP for gas, default injection BHP for water, target gas injection rates, cumulative gas injection volume, cumulative water injection volume, gas cycle length, water cycle length, cumulative gas injection limit, gas injection rate, or water injection rate.

19. The one or more tangible non-transitory computer-readable storage media of claim 15, wherein the one or more control inputs include at least one of maximum gas bottom hole pressure (BHP), maximum water BHP, or priority information.

20. The one or more tangible non-transitory computer-readable storage media of claim 15, wherein the priority information includes at least one of gas and water cycle lengths, equipment location, reservoir pressure, or historical production rates.
